(19) United States
(12) Patent Application Publication
(10) Pub. No.: US 2015/0129724 A1
(43) Pub. Date: May 14, 2015

(54) SUPPORT DEVICE, ATTACHMENT, AND METHOD OF SUPPORTING ELECTRONIC DEVICE

(71) Applicant: Kabushiki Kaisha Toshiba, Tokyo (JP)

(72) Inventors: Yoshinori Kohmoto, Ome-shi (JP); Jun Watanabe, Fussa-shi (JP); Ryo Saito, Nerima-ku (JP); Hirotaka Mitsushio, Ome-shi (JP)

(21) Appl. No.: 14/333,332

(22) Filed: Jul. 16, 2014

(30) Foreign Application Priority Data
Nov. 8, 2013 (JP) 2013-232289

(51) Int. Cl. H05K 5/02; F16B 2/12

(52) U.S. Cl. CPC H05K 5/0204; F16B 2/12
USPC 248/52; 248/316.4; 24/457

(57) ABSTRACT

According to one embodiment, a support device configured to support an electronic device. The electronic device includes a first face and a second face including a recessed portion or a projecting portion. The support device includes a first member and a second member. The first member is configured to support the electronic device. The second member is configured to be movable between a first position and a second position, the first position being a position at which the second member is engaged with the recessed portion or the projecting portion to suppress moving of the electronic device, the second position being a position at which the second member is configured to be separated further from the second face and at which the electronic device is configured to be permitted to move.

### CROSS-REFERENCE TO RELATED APPLICATIONS

This application is based upon and claims the benefit of priority from Japanese Patent Application No. 2013-232289, filed Nov. 8, 2013, the entire contents of which are incorporated herein by reference.

### FIELD

Embodiments described herein relate generally to a support device, an attachment, and a method of supporting an electronic device.

### BACKGROUND

On a support device attached to various places such as a dashboard of a vehicle, a back face of a seat, and a wall of a room, an electronic device is detachably supported.

The electronic device, however, may come off from the support device unintentionally due to vibration and shock, for example.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary diagram illustrating a dashboard of a passenger vehicle according to a first embodiment;

FIG. 2 is an exemplary perspective view illustrating a holder and a tablet in the first embodiment;

FIG. 3 is an exemplary perspective view illustrating the holder and the tablet that are separated from each other, in the first embodiment;

FIG. 4 is an exemplary front view illustrating the tablet in the first embodiment;

FIG. 5 is an exemplary back view illustrating the holder and the tablet in the first embodiment;

FIG. 6 is an exemplary perspective view illustrating the holder in the first embodiment;

FIG. 7 is an exemplary front view illustrating the holder in the first embodiment;

FIG. 8 is an exemplary back view illustrating the holder in the first embodiment;

FIG. 9 is an exemplary front view illustrating a holder and a tablet according to a second embodiment; and

FIG. 10 is an exemplary cross-sectional view illustrating the tablet and a first flap in the second embodiment.

### DETAILED DESCRIPTION

In general, according to one embodiment, a support device configured to detachably support an electronic device. The electronic device comprises a first face configured to be projected an image and a second face comprising a recessed portion or a projecting portion. The support device comprises a first member and a second member. The first member is configured to support the electronic device in a state in which the first face is visible. The second member is configured to be engaged with the recessed portion or the projecting portion, and to be movable between a first position and a second position, the first position being a position at which the second member is engaged with the recessed portion or the projecting portion to suppress moving of the electronic device in at least a first direction along the second face from a position supported by the first member, the second position being a position at which the second member is configured to be separated further from the second face than when the second member is at the first position and at which the electronic device is configured to be permitted to move in the first direction from the supported position.

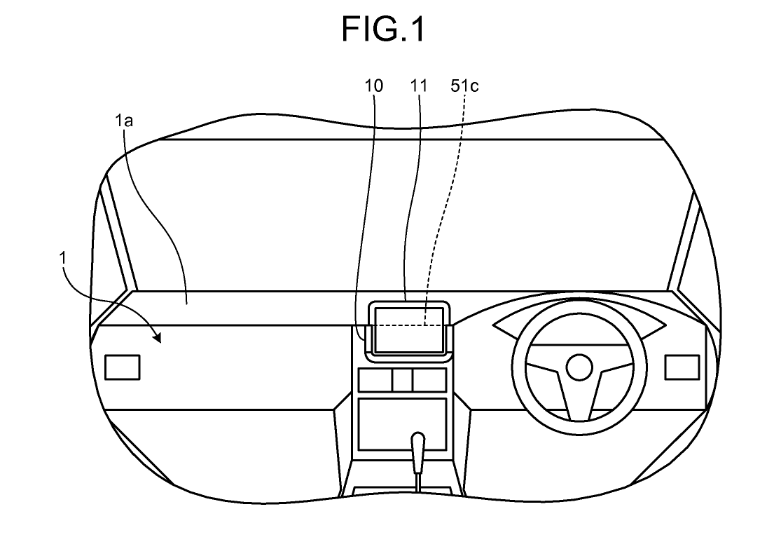

The following describes a first embodiment with reference to FIGS. 1 to 8. In the present specification, basically, the user side is defined as the front, the distal side from the user is defined as the rear, the left side viewed from the user is defined as the left direction, the right side viewed from the user is defined as the right direction, the upper side viewed from the user is defined as the upward direction, and the lower side viewed from the user is defined as the downward direction. Furthermore, the constituent elements in the embodiments and the description of such elements may be expressed in a plurality of ways. Such elements and descriptions are not prevented from being expressed in other ways not expressed in the following description. Moreover, the constituent elements and the descriptions not expressed in a plurality of ways are not prevented from being expressed in a different way.

FIG. 1 schematically illustrates a dashboard 1 of a passenger vehicle. As illustrated in FIG. 1, a holder 10 is secured to a body frame member located internally behind the dashboard 1. The holder 10 is one example of a support device, and can also be referred to as a stand, an attaching device, or a fixing device, for example. Examples of the holder 10 are not limited to this, and the holder 10 may be secured to other places such as a seat of various vehicles like passenger vehicles, trains, and air planes, or a wall of a room.

The holder 10 supports a tablet 11 to be detachable. The tablet 11 is one example of an electronic device and an electronic device assembly. Examples of the electronic device are not limited to the tablet 11, and may be another electronic device such as a tablet PC, an electronic reader, a television receiver, a display, a cellular phone, a smartphone, a personal digital assistant (PDA), a portable game console, or a car navigation system, for example.

The tablet 11 stores therein and processes a variety of applications, and is used for a variety of purposes, for example. The tablet 11 can be used as a television receiver, an audio-video reproduction device, a car navigation system, a monitor in a parking assistance system, and a game console, for example.

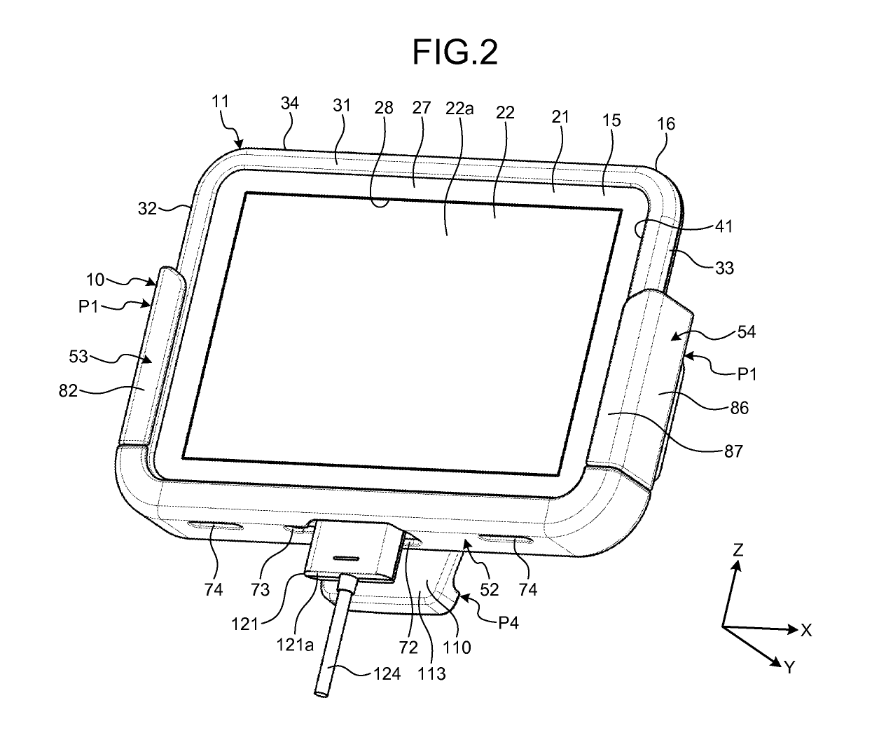

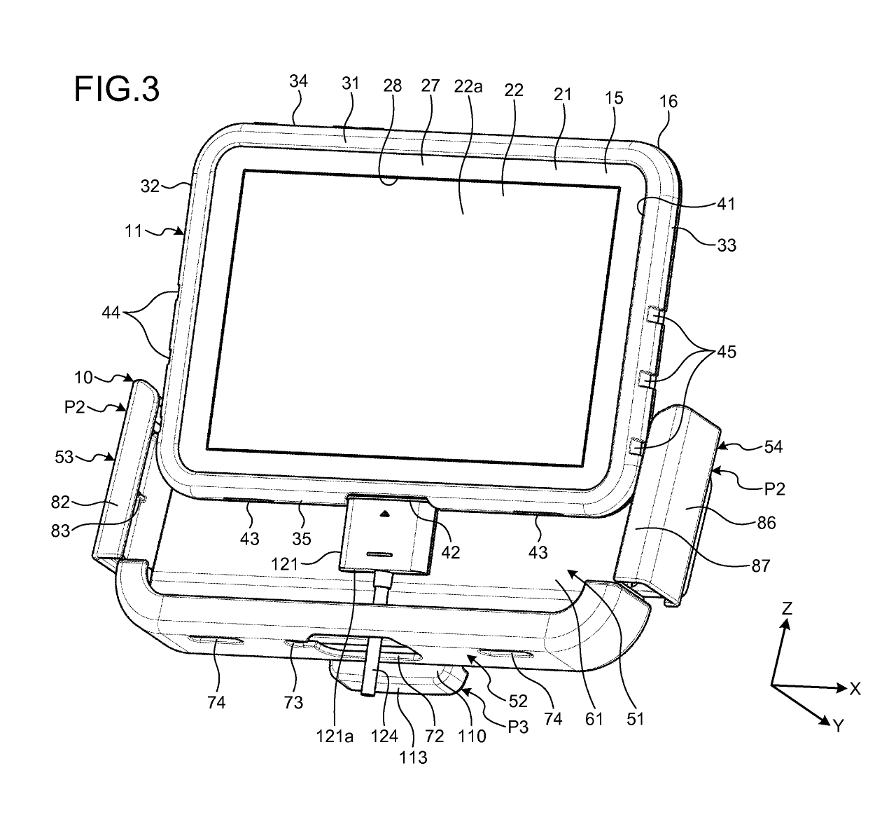

FIG. 2 is a perspective view illustrating the holder 10 and the tablet 11. FIG. 3 is a perspective view illustrating the holder 10 and the tablet 11 that are separated from each other. As illustrated in FIG. 2, the holder 10 holds the tablet 11 in such a state that the length (the length in the long direction) of the tablet 11 in a plate shape is substantially along the horizontal direction and the width (the length in the short direction) of the tablet 11 is substantially along the vertical direction (landscape orientation). The orientation of the tablet 11 that the holder 10 holds is not limited to this.

As illustrated in the drawings, an X axis, a Y axis, and a Z axis are defined in the specification. The X axis, the Y axis, and the Z axis are orthogonal to one another. More specifically, the Y axis is orthogonal to the X axis, and is also orthogonal to the Z axis. The X axis is along the length of the tablet 11. The Y axis is along the thickness of the tablet 11. The Z axis is along the width of the tablet 11.

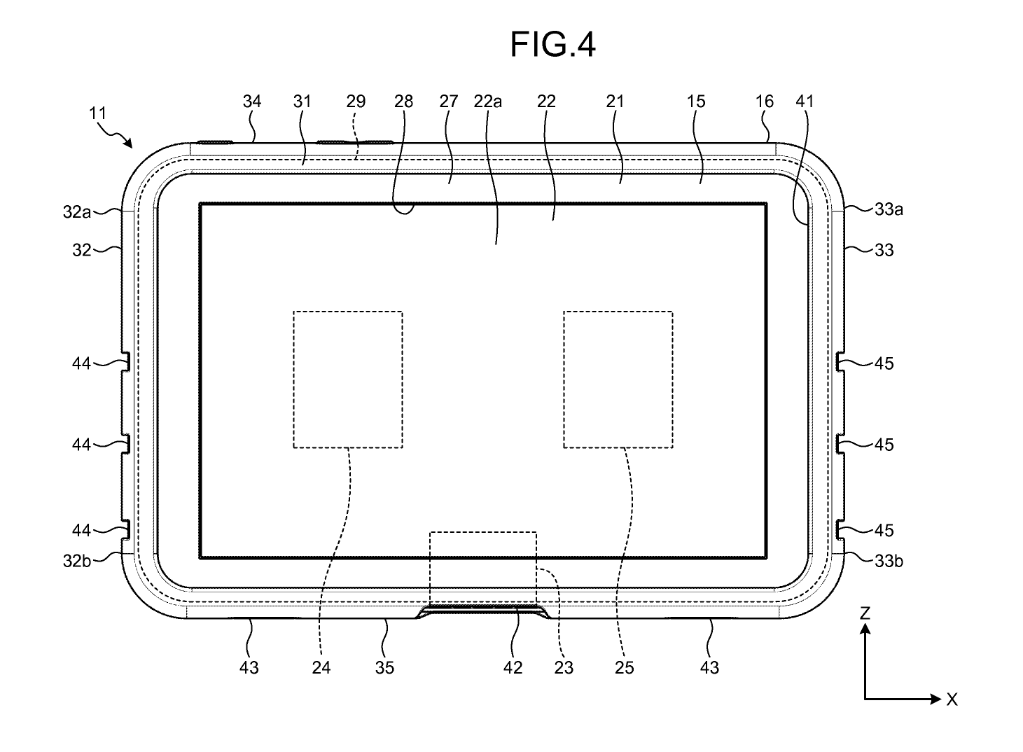

FIG. 4 is a front view illustrating the tablet 11. As illustrated in FIG. 4, the tablet 11 comprises a device 15 and a cover 16. The cover 16 is one example of an attachment, and can also be referred to as a protective member, an exterior member, a case, or a frame, for example. The cover 16 being attached to the device 15 constitutes the tablet 11.

The device 15 is a main body of the tablet 11, and performs a variety of information processes such as outputting images and sound. The device 15 comprises a housing 21, a display module 22, and as indicated by respective broken lines, a first connector 23, a first near field communication (NFC) module 24, and a first wireless power transmission (WPT) module 25. The first connector 23 is one example of a second connecting portion. The device 15 further comprises various components such as a printed circuit board (PCB), a central processing unit (CPU), a pair of speakers, a battery, and connectors.

The housing 21 is formed in a shape of a thin and substantially rectangular (quadrangular) box. The housing 21 comprises a front face 27, a display opening 28, and as indicated by a broken line, a circumferential face 29. The front face 27 is one example of a first face. The housing 21 houses therein the display module 22, the first connector 23, the first NFC module 24, the first WPT module 25, and the various components such as the PCB.

The front face 27 is a flat face of a substantially rectangular (quadrangular) shape. The display opening 28 is provided on the front face 27. The display opening 28 exposes a screen 22a of the display module 22. The display opening 28 is covered with a transparent plate of glass or resin, for example. The display module 22 displays images on the screen 22a. More specifically, the images are displayed on the front face 27. The display module 22 is an in-cell touch panel, for example.

The circumferential face 29 is orthogonal to the front face 27, and forms a circumferential edge of the device 15. The circumferential face 29 opens to the first connector 23. Furthermore, the circumferential face 29 is provided with buttons thereon, and opens to the pair of speakers and an earphone jack, for example.

The first NFC module 24 and the first WPT module 25 are positioned near the back face of the housing 21. The back face of the housing 21 is positioned on the side opposite to the front face 27. Between the first NFC module 24 and the first WPT module 25 and the portions of the back face of the housing 21 corresponding thereto, and near the first NFC module 24 and the first WPT module 25, the installation of a magnetic body such as a metal plate and a magnet is avoided.

The cover 16 is formed of elastomer in a shape of a thin and substantially rectangular (quadrangular) box, for example. Examples of the cover 16 are not limited to this, and may be formed of other material such as metal or synthetic resin, for example. The cover 16 is fitted on the device 15, and covers a part of the front face 27 and the circumferential face 29 of the housing 21. The inner face of the cover 16 contacts the housing 21 of the device 15.

The cover 16 comprises a front face 31, a first side face 32, a second side face 33, an upper face 34, and a lower face 35. The front face 31 is one example of an end portion of the electronic device on one side in a second direction. The first side face 32 and the second side face 33 are examples of a second face. The upper face 34 is one example of an end portion of the electronic device on one side in a first direction. The first side face 32, the second side face 33, the upper face 34, and the lower face 35 can also be referred to as faces, walls, or portions.

As illustrated in FIG. 3, the cover 16 further comprises a first opening portion 41, a second opening portion 42, a pair of third opening portions 43, three pieces of first indentations 44, and three pieces of second indentations 45. The first and the second indentations 44 and 45 are examples of a recessed portion or a projecting portion, and can also be referred to as grooves, fitting portions, attaching portions, fixing portions, braking portions, catching portions, suppressing portions, or clasping portions, for example.

The front face 31 is a flat face that is formed in a shape of a substantially rectangular (quadrangular) frame. The first side face 32, the second side face 33, the upper face 34, and the lower face 35 are orthogonal to the front face 31, and form the circumferential edge of the cover 16. The first side face 32, the second side face 33, the upper face 34, and the lower face 35 are not limited to be flat faces, and they may be curved faces, for example.

The first side face 32 faces in the direction along the X axis. The second side face 33 is positioned on the side opposite to the first side face 32. The upper face 34 faces in the direction along the Z axis. The direction along the Z axis is one example of the first direction. The lower face 35 is positioned on the side opposite to the upper face 34.

The first opening portion 41 is provided on the front face 31. The first opening portion 41 is formed in a substantially rectangular (quadrangular) shape larger than the display opening 28 but smaller than the front face 27 of the housing 21. The first opening portion 41 exposes the front face 27 of the device 15, the display opening 28, and the screen 22a of the display module 22.

The second opening portion 42 is provided on the lower face 35. The second opening portion 42 is provided at the position corresponding to the first connector 23 of the device 15. The second opening portion 42 exposes the first connector 23 that opens to the circumferential face 29.

The pair of third opening portions 43 are provided on the lower face 35. The third opening portions 43 are provided at the positions corresponding to the speakers of the device 15. The third opening portions 43 expose the speakers that open to the circumferential face 29.

As illustrated in FIG. 4, the three first indentations 44 are provided on the first side face 32. The three first indentations 44 are lined and equally spaced apart in the direction along the Z axis, and extend in the direction along the Y axis. The direction along the Y axis is one example of the second direction.

The first indentations 44 are disposed closer toward a lower end portion 32b than an upper end portion 32a of the first side face 32. The upper end portion 32a and the lower end portion 32b are the end portions of the first side face 32 in the direction along the Z axis. The cross section of the first indentation 44 is rectangular (quadrangular), for example. The cross section of the first indentation 44, however, may be in another shape such as a triangle.

The three second indentations 45 are provided on the second side face 33. The three second indentations 45 are lined and equally spaced apart in the direction along the Z axis, and extend in the direction along the Y axis. The second indentations 45 are disposed in mirror symmetry with respect to the first indentations 44. The positions of the second indentations 45 are, however, not limited to these.

The second indentations 45 are disposed closer toward a lower end portion 33b than an upper end portion 33a of the second side face 33. The upper end portion 33a and the lower end portion 33b are the end portions of the second side face 33 in the direction along the Z axis. The cross section of the second indentation 45 is rectangular (quadrangular), for example. The cross section of the second indentation 45 may be in another shape such as a triangle.

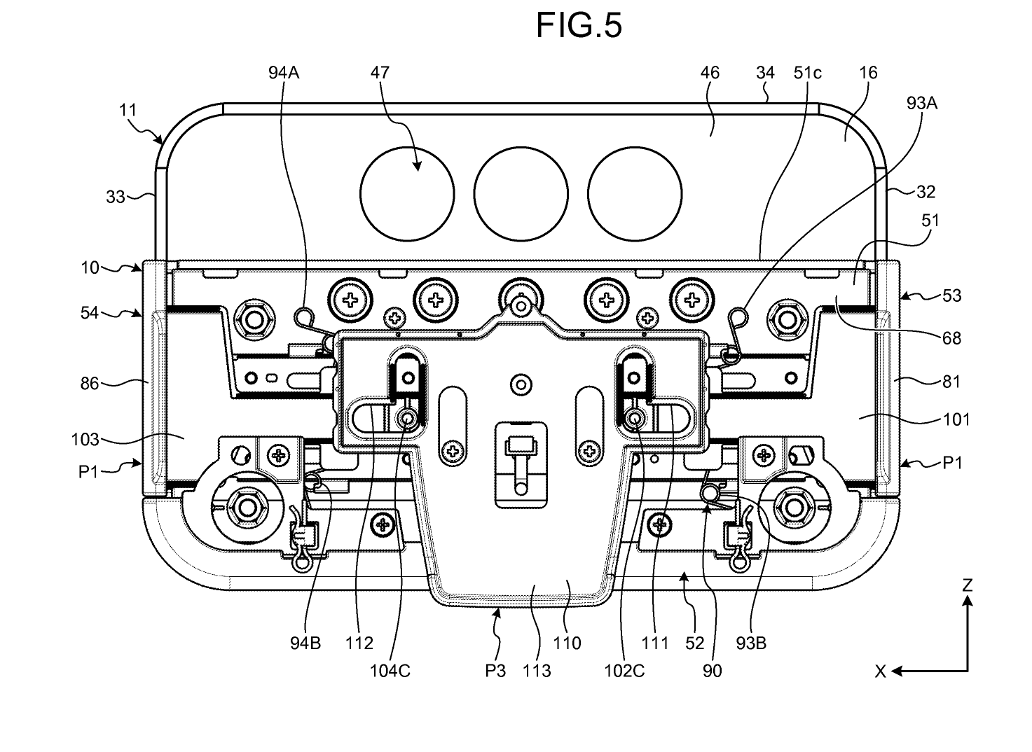

FIG. 5 is a back view illustrating the holder 10 and the tablet 11. As illustrated in FIG. 5, the cover 16 further comprises a back face 46. The back face 46 is one example of an end portion of the electronic device on the other side in the second direction. The back face 46 is positioned on the side opposite to the front face 31. The back face 46 is a flat face of a substantially rectangular (quadrangular) shape.

The back face 46 is provided with a logo 47. The logo 47 can also be referred to as a display portion, characters, or graphics, for example. The logo 47 is a portion of a recessed portion, a projecting portion, or a sticker-attached or painted portion, and represents characters and/or graphics, for example. The logo 47 is located at a position closer to the upper face 34 than the lower face 35.

As in the foregoing, the cover 16 covers the outer face of the device 15 and exposes the front face 27 of the device 15. Examples of the cover 16 are not limited to this, and the cover 16 may expose the back face of the device 15 or may expose a part of the circumferential face 29 of the device 15.

All the portions of the cover 16 may not need to be formed of the elastomer. For example, the portions in which the first and the second indentations 44 and 45 are provided may be more reinforced than the other portions. The reinforced portions are formed of a harder material than that of the other portions or are internally provided with metal members, for example. Furthermore, the other portions may be formed of a soft material (deforms easily, has elasticity, or has flexibility) to make the cover 16 easy to fit onto the device 15 and easy to remove from the device 15.

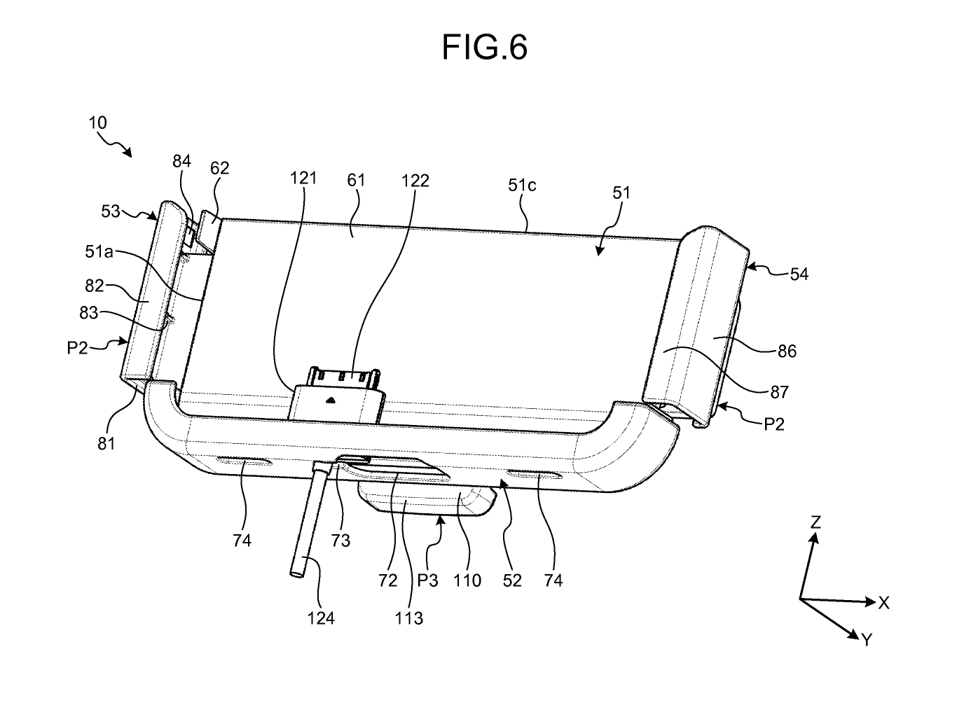

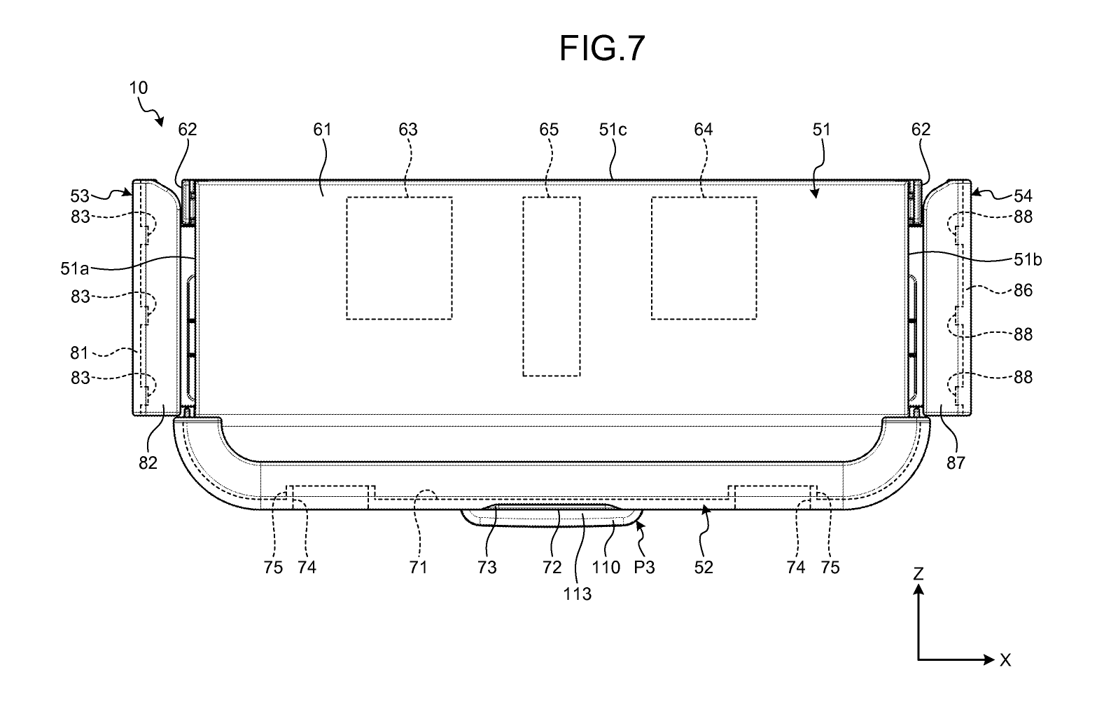

FIG. 6 is a perspective view illustrating the holder 10. FIG. 7 is a front view illustrating the holder 10. As illustrated in FIG. 7, the holder 10 comprises a back board 51, a bottom plate 52, a first flap 53, and a second flap 54. The back board 51 is one example of a second wall, and can also be referred to as a wall, a supporting portion, or a sandwiching portion, for example. The bottom plate 52 is one example of a first member, and can also be referred to as a wall, a supporting portion, a fixing portion, or a placement portion, for example. The first and the second flaps 53 and 54 are examples of a second member, and can also be referred to as walls, members, stoppers, holding portions, fixing portions, movable portions, or sandwiching portions, for example.

The back board 51 comprises a supporting face 61, a pair of supporting pieces 62, and as indicated by respective broken lines, a second NFC module 63, a second WPT module 64, and a magnet 65. The second NFC module 63 may also be referred to as a communicating portion, for example. The second WPT module 64 may also be referred to as a power feeding portion, for example. The magnet 65 may also be referred to as an attaching portion, a clasping portion, or an attracting portion, for example.

The supporting face 61 is a flat face of a substantially rectangular (quadrangular) shape. The supporting face 61 is formed of resin that is an insulating material and a non-magnetic material, for example. The supporting face 61 may be formed of other material such as synthetic rubber and metal.

The supporting face 61 is a face that faces in the direction along the Y axis. The supporting face 61 faces the back face 46 of the cover 16 for the tablet 11, and supports the tablet 11. The supporting face 61 supports the tablet 11 from the lower face 35 of the tablet 11 over to an intermediate portion positioned between the upper face 34 and the lower face 35. As illustrated in FIG. 5, a part of the back face 46 of the cover 16 from the intermediate portion over to the upper face 34 is not covered with the backboard 51 but exposed. The logo 47 is disposed at the part of the back face 46, and thus exposed not being covered with the back board 51.

As illustrated in FIG. 7, the pair of supporting pieces 62 are disposed at side edge portions 51a and 51b of the back board 51 in the direction along the X axis. Furthermore, the pair of supporting pieces 62 are disposed at positions contacting an upper end portion 51c of the back board 51 in the direction along the Z axis. The supporting pieces 62 project in the direction along the Y axis from the supporting face 61. The supporting pieces 62 are plates of a substantially rectangular (quadrangular) shape, for example.

The distance between the pair of supporting pieces 62 is slightly longer than the distance (length) between the first side face 32 and the second side face 33 of the cover 16. When the tablet 11 is supported on the supporting face 61, the tablet 11 is positioned between the pair of supporting pieces 62.

The second NFC module 63 and the second WPT module 64 are disposed behind the back board 51. The second NFC module 63 performs wireless communication with the first NFC module 24 of the tablet 11 supported on the supporting face 61. The second WPT module 64 generates an electromotive force on a coil in the first WPT module 25 of the tablet 11 supported on the supporting face 61 so as to supply electrical power to the tablet 11, for example.

The magnet 65 is disposed behind the back board 51. The tablet 11 comprises a magnetic body, for example, of a steel plate. The magnet 65 attracts the magnetic body provided on the tablet 11. Consequently, the magnet 65 makes the tablet 11 adhere to the back board 51.

As illustrated in FIG. 5, the back board 51 further comprises a rear portion 68. The rear portion 68 is positioned on the side opposite to the supporting face 61. The rear portion 68 is mounted with a mounting bracket, for example. The mounting bracket secures the holder 10 to the body frame member located behind the dashboard 1, for example.

As illustrated in FIG. 1, the holder 10 is disposed on the dashboard 1 such that the upper end portion 51c of the back board 51 is along an upper face 1a of the dashboard 1. Consequently, as illustrated in FIG. 5, this makes the logo 47 visible from outside the passenger vehicle. The holder 10 may comprise a light source to illuminate the logo 47, for example.

As illustrated in FIG. 7, the bottom plate 52 extends in the direction along the X axis. The bottom plate 52 comprises a bottom face 71, a first opening 72, a second opening 73, and as indicated by respective broken lines, a pair of third openings 74, and a pair of ribs 75. The first and the second openings 72 and 73 are examples of an opening portion. The first and the second openings 72 and 73 can also be referred to as an inserted portion or a passed portion, for example.

The bottom face 71 is a face that faces in the direction along the Z axis, and faces the lower face 35 of the cover 16 for the tablet 11. The first opening 72, the second opening 73, and the third openings 74 open to the bottom face 71.

As illustrated in FIG. 6, the first opening 72 is a through hole of a substantially rectangular (quadrangular) shape extending in the direction along the X axis. The first opening 72 is located at the position corresponding to the first connector 23 of the device 15 and the second opening portion 42 of the cover 16. The first opening 72 exposes the first connector 23 that is exposed by the second opening portion 42.

The second opening 73 is lined with the first opening 72 in the direction along the X axis. The second opening 73 connects to the first opening 72. In other words, the first and the second openings 72 and 73 form a single opening. The second opening 73 is smaller than the first opening 72, and is formed in a round shape, for example. The second opening 73 may be formed in another shape.

The pair of third openings 74 are located at the positions corresponding to the pair of speakers of the device 15 and the pair of third opening portions 43 of the cover 16. The third openings 74 expose the speakers that are exposed by the third opening portions 43.

As illustrated in FIG. 7, the pair of ribs 75 are provided at the edges of the pair of third openings 74. The ribs 75 project in the direction along the Z axis from the bottom face 71. The tips of the ribs 75 contact the lower face 35 of the cover 16. More specifically, the ribs 75 support the lower face 35 of the cover 16 for the tablet 11.

As illustrated in FIG. 6, the first flap 53 comprises a first side wall 81, a first front wall 82, three pieces of first protrusions 83, and a buffer 84. The first front wall 82 is one example of a first wall. The first side wall 81 and the first front wall 82 can also be referred to as a wall, a stopper, a sandwiching portion, an abutment portion, or a contacting portion, for example. The first protrusions 83 can also be referred to as projecting portions, fitting portions, stoppers, fixing portions, attaching portions, braking portions, clasping portions, catching portions, suppressing portions, or engaging portions, for example.

The first side wall 81 extends in the direction along the Z axis, and faces in the direction along the X axis. The first side wall 81 faces the first side face 32 of the cover 16. A part of the first side wall 81 faces the supporting piece 62 positioned at the side edge portion 51a of the back board 51.

The first front wall 82 is orthogonal to the first side wall 81. The first front wall 82 extends in the direction along the Z axis, and faces in the direction along the Y axis. The first front wall 82 faces the supporting face 61 of the back board 51, and faces the front face 31 of the cover 16 for the tablet 11 supported on the supporting face 61.

The three first protrusions 83 protrude in the direction along the X axis from the first side wall 81. The first protrusions 83 extend in the direction along the Y axis. The three first protrusions 83 are disposed at the respective positions corresponding to the three first indentations 44 of the cover 16.

The buffer 84 is attached to the portion of the first side wall 81 facing the supporting piece 62. While the buffer 84 is formed of synthetic rubber, for example, the buffer 84 may be made of other material.

As illustrated in FIG. 7, the second flap 54 comprises a second side wall 86, a second front wall 87, and three pieces of second protrusions 88. The second front wall 87 is one example of the first wall. The second side wall 86 and the second front wall 87 can also be referred to as a wall, a stopper, a sandwiching portion, an abutment portion, or a contacting portion, for example. The second protrusions 88 can also be referred to as projecting portions, fitting portions, stoppers, fixing portions, attaching portions, braking portions, clasping portions, catching portions, suppressing portions, or engaging portions, for example.

The second side wall 86 extends in the direction along the Z axis, and faces in the direction along the X axis. This makes the second side wall 86 face the first side wall 81. The second side wall 86 faces the second side face 33 of the cover 16.

A part of the second side wall 86 faces the supporting piece 62 positioned at the side edge portion 51b of the back board 51. The part of the second side wall 86 is attached with a buffer. The buffer is formed of synthetic rubber, for example.

The second front wall 87 is orthogonal to the second side wall 86. The second front wall 87 extends in the direction along the Z axis, and faces in the direction along the Y axis. The second front wall 87 faces the supporting face 61 of the back board 51, and faces the front face 31 of the cover 16 for the tablet 11 supported on the supporting face 61.

The three second protrusions 88 protrude in the direction along the X axis from the second side wall 86. The second protrusions 88 protrude toward the first flap 53. The second protrusions 88 extend in the direction along the Y axis. The three second protrusions 88 are disposed at the respective positions corresponding to the three second indentations 45 of the cover 16.

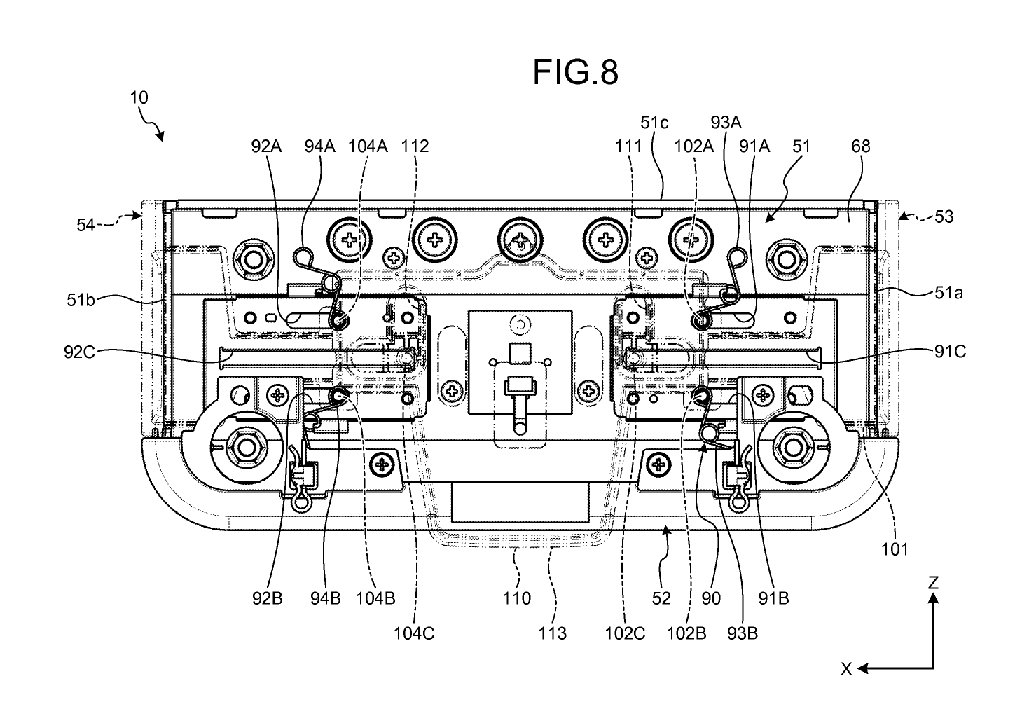

FIG. 8 is a back view illustrating the holder 10. As illustrated in FIG. 8, the holder 10 further comprises a sliding portion 90. The sliding portion 90 is one example of a biasing portion, and can also be referred to as a moving portion, a pushing portion, a pulling portion, or a mechanism, for example.

The sliding portion 90 is provided on the rear portion 68 of the back board 51. The sliding portion 90 comprises three pieces of first slits 91A, 91B, and 91C; three pieces of second slits 92A, 92B, and 92C; two pieces of first torsion springs 93A and 93B; and two pieces of second torsion springs 94A and 94B.

The first slits 91A, 91B, and 91C and the second slits 92A, 92B, and 92C extend in the direction along the X axis. The first slits 91A, 91B, and 91C are closer to the side edge portion 51a of the back board 51 on one side than the second slits 92A, 92B, and 92C. The second slits 92A, 92B, and 92C are closer to the side edge portion 51b of the back board 51 on the other side than the first slits 91A, 91B, and 91C. The three first slits 91A, 91B, and 91C are lined in the direction along the Z axis. The three second slits 92A, 92B, and 92C are lined in the direction along the Z axis.

The first flap 53 further comprises a first arm 101 and three pieces of first projecting portions 102A, 102B, and 102C. The first arm 101 extends in the direction along the X axis from the first side wall 81. The first projecting portions 102A, 102B, and 102C project in the direction along the Y axis from the first arm 101. The first projecting portions 102A, 102B, and 102C are columnar protrusions, for example.

The first projecting portions 102A, 102B, and 102C fit in the first slits 91A, 91B, and 91C corresponding thereto. The first projecting portions 102A, 102B, and 102C are movable in the direction along the X axis in the first slits 91A, 91B, and 91C, respectively. This makes the first flap 53 movable in the direction along the X axis.

The first flap 53 is movable between a first position P1 (as indicated by dashed-two dotted lines in FIG. 8, for example) and a second position P2 (as illustrated in FIG. 6, for example). At the first position P1, the first side wall 81 contacts the supporting piece 62 positioned at the side edge portion 51a of the back board 51 via the buffer 84. At the second position P2, the first side wall 81 is separated from the supporting piece 62.

The second flap 54 further comprises a second arm 103 and three pieces of second projecting portions 104A, 104B, and 104C. The second arm 103 extends in the direction along the X axis from the second side wall 86. The second projecting portions 104A, 104B, and 104C project in the direction along the Y axis from the second arm 103. The second projecting portions 104A, 104B, and 104C are columnar protrusions, for example.

The second projecting portions 104A, 104B, and 104C fit in the second slits 92A, 92B, and 92C corresponding thereto. The second projecting portions 104A, 104B, and 104C are movable in the direction along the X axis in the second slits 92A, 92B, and 92C, respectively. This makes the second flap 54 movable in the direction along the X axis.

The second flap 54 is movable between the first position P1 (as indicated by dashed-two dotted lines in FIG. 8, for example) and the second position P2 (as illustrated in FIG. 6, for example). At the first position P1, the second side wall 86 contacts the supporting piece 62 positioned at the side edge portion 51b of the back board 51 via the buffer. At the second position P2, the second side wall 86 is separated from the supporting piece 62.

The end portions of the first torsion springs 93A and 93B on one side are rotatably attached to respective pins provided on the rear portion 68 of the back board 51, for example. The end portions of the first torsion springs 93A and 93B on the other side are rotatably attached to the first projecting portions 102A and 102B corresponding thereto.

When the first flap 53 is located at a position closer to the first position P1 than in the middle of the first position P1 and the second position P2, the first torsion springs 93A and 93B push the first flap 53 toward the first position P1. Meanwhile, when the first flap 53 is located at a position closer to the second position P2 than in the middle of the first position P1 and the second position P2, the first torsion springs 93A and 93B push the first flap 53 toward the second position P2.

The end portions of the second torsion springs 94A and 94B on one side are rotatably attached to respective pins provided on the rear portion 68 of the back board 51, for example. The end portions of the second torsion springs 94A and 94B on the other side are rotatably attached to the second projecting portions 104A and 104B corresponding thereto.

When the second flap 54 is located at a position closer to the first position P1 than in the middle of the first position P1 and the second position P2, the second torsion springs 94A and 94B push the second flap 54 toward the first position P1. Meanwhile, when the second flap 54 is located at a position closer to the second position P2 than in the middle of the first position P1 and the second position P2, the second torsion springs 94A and 94B push the second flap 54 toward the second position P2.

As in the foregoing, the sliding portion 90 pushes the first and the second flaps 53 and 54 toward the first position P1 or the second position P2. In other words, the sliding portion 90 exerts a force toward the first position P1 or the second position P2 to the first and the second flaps 53 and 54. More specifically, the sliding portion 90 comprises what is called a bistable spring. Examples of the sliding portion 90 are not limited to this, and may push the first and the second flaps 53 and 54 only toward the first position P1, for example.

As indicated by dashed-two dotted lines in FIG. 8, the holder 10 further comprises a lock lever 110. The lock lever 110 is one example of a locking portion, and may be referred to as a stopper, a fixing portion, a holding portion, or a clasping portion, for example. The lock lever 110 comprises a third slit 111, a fourth slit 112, and an operated portion 113.

The third and the fourth slits 111 and 112 are formed in a substantially L-shape. More specifically, parts of the third and the fourth slits 111 and 112 extend in the direction along the X axis. The other parts of the third and the fourth slits 111 and 112 extend in the direction along the Z axis.

The first projecting portion 102C of the first flap 53 passes through the first slit 91C and fits in the third slit 111. The first projecting portion 102C is movable along the portion of the third slit 111 extending along the X axis.

The second projecting portion 104C of the second flap 54 passes through the second slit 92C and fits in the fourth slit 112. The second projecting portion 104C is movable along the portion of the fourth slit 112 extending along the X axis.

When the first and the second flaps 53 and 54 are located at the first position P1, the first and the second projecting portions 102C and 104C are positioned at the respective end portions of the third and the fourth slits 111 and 112. From the respective end portions thereof, the portions of the third and the fourth slits 111 and 112 extending in the direction along the Z axis extend.

The lock lever 110 is attached to the rear portion 68 of the back board 51 to be movable along the Z axis. The lock lever 110 is movable between a release position P3 (as indicated by dashed-two dotted lines in FIG. 8, for example) and a fix position P4 (as illustrated in FIG. 2, for example).

When the lock lever 110 is located at the release position P3, the first and the second projecting portions 102C and 104C are positioned at the respective portions of the third and the fourth slits 111 and 112 extending along the X axis. Consequently, the lock lever 110 does not interfere with the move of the first and the second flaps 53 and 54. In other words, the lock lever 110 permits the first and the second flaps 53 and 54 to move.

When the lock lever 110 is moved to the fix position P4, the first and the second projecting portions 102C and 104C are disposed at the respective portions of the third and the fourth slits 111 and 112 extending along the Z axis. The first and the second projecting portions 102C and 104C hit against the respective edges of the third and the fourth slits 111 and 112, and are restricted to move along the X axis. More specifically, the move of the first and the second flaps 53 and 54 in the direction along the X axis is restricted by the lock lever 110.

When the lock lever 110 located at the fix position P4 is moved to the release position P3, the first and the second projecting portions 102C and 104C move to the respective portions of the third and the fourth slits 111 and 112 extending along the X axis. This releases the restriction of the first and the second flaps 53 and 54 to move.

When both of the first and the second flaps 53 and 54 are located at the first position P1, the lock lever 110 is movable from the release position P3 to the fix position P4. In other words, the first and the second flaps 53 and 54 located at the second position P2 restrict the lock lever 110 to move from the release position P3 to the fix position P4. The lock lever 110 may be configured to be movable from the release position P3 to the fix position P4 when at least one of the first and the second flaps 53 and 54 is located at the second position P2.

The operated portion 113 extends in the direction along the Z axis. The operated portion 113 projects downward from the bottom plate 52. At least a part of the operated portion 113 is visible to the driver of the passenger vehicle even when the lock lever 110 is located at the release position P3 and even when the lock lever 110 is located at the fix position P4.

As illustrated in FIG. 3, the tablet 11 is connected with a second connector 121. The second connector 121 is one example of a first connecting portion, and can also be referred to as a plug, a connecting component, or an attaching component, for example. The second connector 121 comprises a terminal 122 illustrated in FIG. 6.

Extending from a bottom face 121a of the second connector 121 is a cable 124. The cable 124 is one example of wiring, and can also be referred to as a cord or a harness, for example. The bottom face 121a is positioned on the side opposite to the terminal 122. The cable 124 is connected to a module disposed behind the dashboard 1, for example. The area of the bottom face 121a of the second connector 121 is larger than the cross-sectional area of the cable 124.

As illustrated in FIG. 2, the second connector 121 is inserted through the first opening 72 of the holder 10 and the second opening portion 42 of the cover 16. The terminal 122 of the second connector 121 is inserted to the first connector 23 of the device 15. This detachably connects the second connector 121 to the first connector 23. Via the second connector 121 and the cable 124, the device 15 receives the supply of electrical power and performs sending and receiving of an electrical signal, for example.

The following describes one example of a method of supporting (docking) the tablet 11 by the holder 10. The method of supporting the tablet 11 by the holder 10 is, however, not limited to the one described in the following.

First, as illustrated in FIG. 6, the lock lever 110 is disposed at the release position P3. The first and the second flaps 53 and 54 are then moved to the respective positions of the second position P2. In other words, the first and the second flaps 53 and 54 move away from each other.

Next, as illustrated in FIG. 3, the second connector 121 is connected to the first connector 23 of the device 15. The tablet 11 is then placed between the pair of supporting pieces 62. More specifically, the tablet 11 is placed at the position at which the lower face 35 of the cover 16 is supported by the ribs 75 of the bottom plate 52 and the back face 46 of the cover 16 is supported on the supporting face 61 of the back board 51. The bottom plate 52 supports the tablet 11 such that the front face 27 of the device 15 is visible. The magnet 65 attracts the tablet 11 and makes the tablet 11 adhere to the supporting face 61. The second connector 121 is disposed in the first opening 72.

Next, as illustrated in FIG. 2, the first and the second flaps 53 and 54 located at the second position P2 are moved to the first position P1. The first side wall 81 of the first flap 53 moved to the first position P1 hits against the first side face 32 of the cover 16. Furthermore, the second side wall 86 of the second flap 54 moved to the first position P1 hits against the second side face 33 of the cover 16. There may be clearance between the first side wall 81 and the first side face 32, and between the second side wall 86 and the second side face 33. The first side wall 81 and the second side wall 86 sandwich the tablet 11. This makes the holder 10 restrict the tablet 11 to move in the direction along the X axis.

When the first and the second flaps 53 and 54 are moved to the first position P1, the first and the second side walls 81 and 86 hit against the respective supporting pieces 62. The buffer 84 provided on the first side wall 81 and the buffer provided on the second side wall 86 reduce the sound generated by the first and the second side walls 81 and 86 colliding with the respective supporting pieces 62.

Moreover, the three first protrusions 83 of the first flap 53 moved to the first position P1 fit in the three first indentations 44 of the cover 16. The three second protrusions 88 of the second flap 54 moved to the first position P1 fit in the three second indentations 45 of the cover 16.

The first and the second protrusions 83 and 88 catch the first and the second indentations 44, 45 when the tablet 11 is attempted to move in the direction along the Z axis from the position supported on the bottom plate 52. More specifically, the first and the second protrusions 83 and 88 prevent the tablet 11 from moving in the direction along the Z axis. In other words, the holder 10 restricts the tablet 11 to move in the direction along the Z axis.

Furthermore, the first front wall 82 of the first flap 53 moved to the first position P1 and the second front wall 87 of the second flap 54 moved to the first position P1 contact the front face 31 of the cover 16. More specifically, the supporting face 61 of the back board 51 and the first and the second front walls 82 and 87 sandwich the tablet 11. This makes the holder 10 restrict the tablet 11 to move in the direction along the Y axis.

Next, the lock lever 110 located at the release position P3 is moved to the fix position P4. This prevents the first and the second flaps 53 and 54 from moving from the first position P1 to the second position P2. In this manner, the holder 10 supports the tablet 11.

The operated portion 113 of the lock lever 110 is positioned behind the second connector 121. More specifically, the second connector 121 hides the operated portion 113. This prevents the lock lever 110 from moving from the fix position P4 to the release position P3 by careless operation.

As in the foregoing, the holder 10 restricts the tablet 11 to move in the directions along the X axis, the Y axis, and the Z axis (three axes). More specifically, the holder 10 holds the tablet 11 so as to prevent the tablet 11 from moving.

When the holder 10 holds the tablet 11, the first flap 53 covers roughly a lower half of the first side face 32 of the cover 16. In other words, the first flap 53 covers the first side face 32 from the lower end portion 32b over to an intermediate portion positioned between the upper end portion 32a and the lower end portion 32b. The portion of the first side face 32 from the intermediate portion to the upper end portion 32a is exposed.

Furthermore, the second flap 54 covers roughly a lower half of the second side face 33 of the cover 16. In other words, the second flap 54 covers the second side face 33 from the lower end portion 33b over to an intermediate portion positioned between the upper end portion 33a and the lower end portion 33b. The portion of the second side face 33 from the intermediate portion to the upper end portion 33a is exposed.

Moreover, when the first and the second flaps 53 and 54 are located at the first position P1 and the tablet 11 is supported on the bottom plate 52, the upper face 34 of the cover 16 is not covered with the holder 10 but exposed. The upper face 34 is positioned between the upper end portion 32a of the first side face 32 and the upper end portion 33a of the second side face 33.

When the tablet 11 is removed from the holder 10, the lock lever 110 located at the fix position P4 is moved to the release position P3 first. The first and the second flaps 53 and 54 located at the first position P1 are then moved to the second position P2. More specifically, the first side wall 81 is separated from the first side face 32 of the cover 16, and the first protrusions 83 are disengaged from the first indentations 44. Furthermore, the second side wall 86 is separated from the second side face 33 of the cover 16, and the second protrusions 88 are disengaged from the second indentations 45. The first and the second side walls 81 and 86 at the second position P2 are separated further from the first and the second side faces 32 and 33 corresponding thereto than those at the first position P1.

When the first and the second protrusions 83 and 88 are disengaged from the first and the second indentations 44 and 45 corresponding thereto, the tablet 11 is movable in the direction along the Z axis from the position supported on the bottom plate 52. In other words, the first and the second flaps 53 and 54 located at the second position P2 permit the tablet 11 to move in the direction along the Z axis.

Next, as illustrated in FIG. 3, the tablet 11 is pulled away from the back board 51 and the bottom plate 52 of the holder 10. The second connector 121 is pulled up through the first opening 72 of the holder 10. The cable 124 passes the first opening 72.

The second connector 121 is then removed from the first connector 23 of the device 15. As illustrated in FIG. 6, the cable 124 is moved from the first opening 72 to the second opening 73. The bottom face 121a of the second connector 121 is placed on the bottom face 71 of the bottom plate 52. In other words, the second connector 121 is caught in the edge portion of the second opening 73 of the bottom plate 52. More specifically, the edge portion of the second opening 73 is one example of a catching portion. In the foregoing manner, the tablet 11 is removed from the holder 10.

When the tablet 11 is removed from the holder 10, the tablet 11 projecting from the upper face 1a of the dashboard 1 is eliminated. The upper end portion 51c of the back board 51 of the holder 10 is along the upper face 1a of the dashboard 1. Furthermore, the upper end portions of the first and the second side walls 81 and 86 are also along the upper face 1a of the dashboard 1. Consequently, this broadens the view of the driver in the passenger vehicle.

In the holder 10 and the tablet 11 in the first embodiment, the first and the second side walls 81 and 86 sandwiching the tablet 11 restricts the tablet 11 to move in the direction along the X axis. Furthermore, the first and the second protrusions 83 and 88 fitting in the first and the second indentations 44 and 45 of the cover 16 for the tablet 11, respectively, restricts the tablet 11 to move in the direction along the Z axis. By the sandwiching and fitting, the holder 10 restricts the tablet 11 to move in a plurality of directions. Consequently, even when a massive impact by the collision of the passenger vehicle is exerted to the holder 10, for example, the tablet 11 is prevented from coming off from the holder 10.

The back board 51 and the first and the second front walls 82 and 87 sandwiching the tablet 11 restricts the tablet 11 to move in the direction along the Y axis. By the sandwiching and fitting, the holder 10 thus restricts the tablet 11 to move in the directions along the three axes. This further prevents the tablet 11 from coming off from the holder 10.

The lock lever 110 located at the fix position P4 restricts the first and the second flaps 53 and 54 to move. This prevents the tablet 11 from being released from being sandwiched and fitted by the holder 10, and thus further prevents the tablet 11 from coming off from the holder 10.

The sliding portion 90 pushes the first and the second flaps 53 and 54 toward the first position P1. This prevents the tablet 11 from being released from being sandwiched and fitted by the holder 10, and thus further prevents the tablet 11 from dropping off from the holder 10.

A part of the first side face 32, a part of the second side face 33, and the upper face 34 of the tablet 11 are not covered with the holder 10 but exposed. This permits the holder 10 to be downsized, and thus a limited space such as the inside of the passenger vehicle can be used more widely, for example. Furthermore, this reduces the narrowing of the view of the driver in the passenger vehicle ahead of the holder 10, which may be caused by the holder 10.

The bottom plate 52 supports the second connector 121 in a state of the cable 124 passing the second opening 73. This prevents the second connector 121 from dropping off from the holder 10 even when the second connector 121 is disconnected from the tablet 11.

The back board 51 comprises the magnet 65. The magnet 65 makes the tablet 11 adhere onto the supporting face 61 of the backboard 51, and thus prevents the tablet 11 from being separated from the back board 51 and coming off from the holder 10.

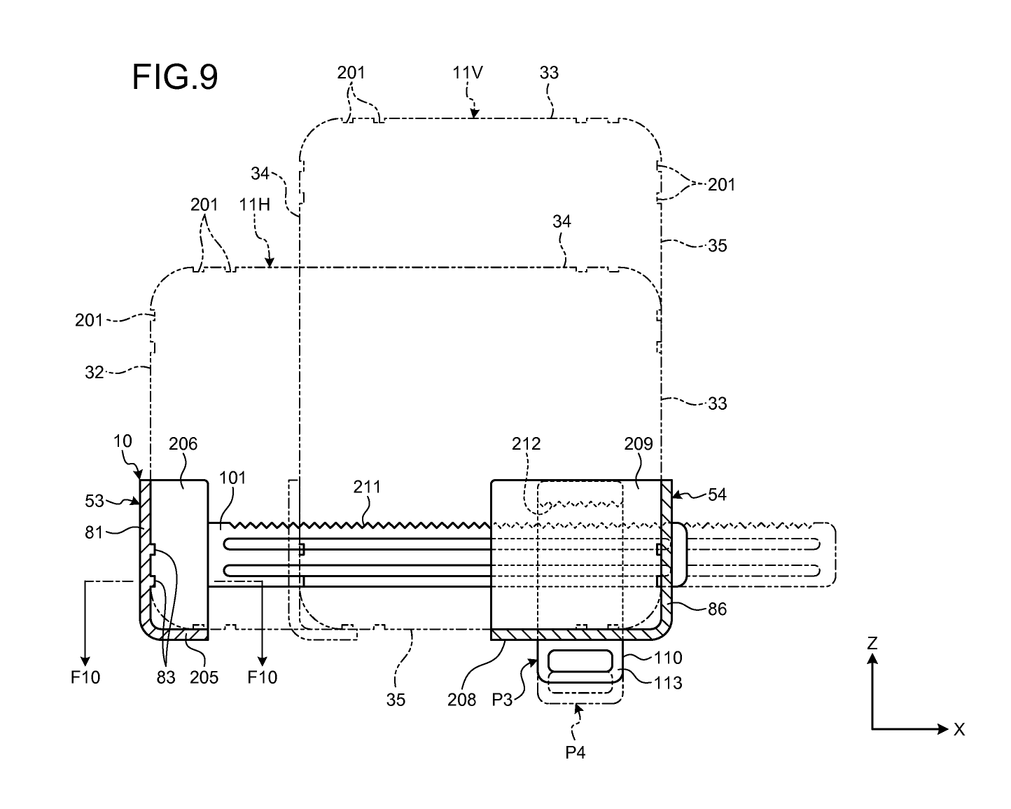

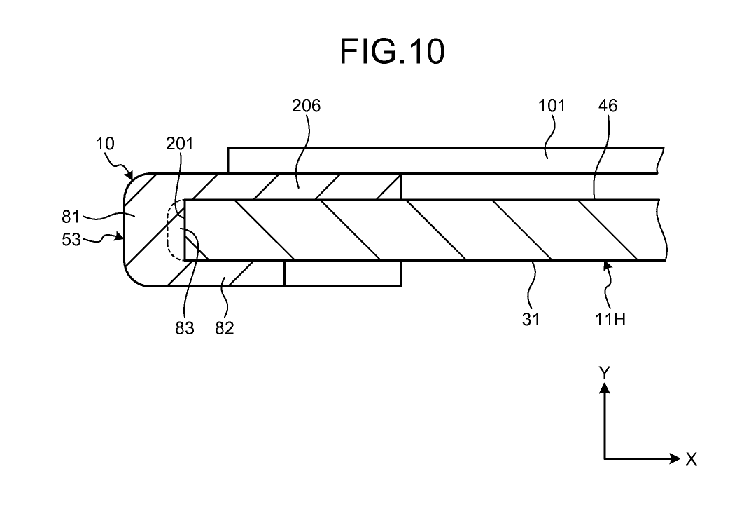

The following describes a second embodiment with reference to FIGS. 9 and 10. In the following description of the embodiment, the constituent elements having the same or similar functions as those of the constituent elements that have already been explained are given with the same reference numerals or symbols as those of the already-described constituent elements, and the explanations thereof may further be omitted. Moreover, a plurality of constituent elements given with the same reference numerals or symbols may not necessarily share all of the functions and characteristics in common, and may have different functions and characteristics in accordance with each of the embodiments.

FIG. 9 is a front view schematically illustrating the holder 10 and the tablet 11 in the second embodiment. In FIG. 9, the tablet 11 is indicated by dashed-two dotted lines.

As illustrated in FIG. 9, the tablet 11 in the second embodiment comprises a plurality of indentations 201 in place of the first and the second indentations 44 and 45. The indentations 201 are examples of a recessed portion or a projecting portion. The indentations 201 are provided on each of the first side face 32, the second side face 33, the upper face 34, and the lower face 35 of the cover 16.

The holder 10 in the second embodiment does not comprise the back board 51, the bottom plate 52, or the sliding portion 90. The lock lever 110 is provided on the second flap 54. The mounting bracket is also provided on the second flap 54, and attaches the second flap 54 to the dashboard 1, for example.

The first flap 53 in the second embodiment comprises a first supporting wall 205 and a first back wall 206. The first supporting wall 205 is one example of a first member. The first back wall 206 is one example of a second wall. The first supporting wall 205 extends in the direction along the X axis from the lower end of the first side wall 81. The first supporting wall 205 faces the lower face 35 of the cover 16 for the tablet 11.

FIG. 10 is a cross-sectional view taken along the line F10-F10 in FIG. 9, illustrating the tablet 11 and the first flap 53. As illustrated in FIG. 10, the first back wall 206 faces the first front wall 82. The first back wall 206 faces the back face 46 of the cover 16 for the tablet 11.

As illustrated in FIG. 9, the second flap 54 in the second embodiment comprises a second supporting wall 208 and a second back wall 209. The second supporting wall 208 is one example of the first member. The second back wall 209 is one example of the second wall. The second flap 54 does not comprise the second protrusions 88 or the second arm 103.

The second supporting wall 208 extends in the direction along the X axis from the lower end of the second side wall 86. The second supporting wall 208 faces the lower face 35 of the cover 16 for the tablet 11. The second back wall 209 faces the second front wall 87. The second back wall 209 faces the back face 46 of the cover 16 for the tablet 11.

The first arm 101 comprises a plurality of first teeth 211. The first teeth 211 point to the direction along the Z axis. The lock lever 110 comprises a plurality of second teeth 212. The second teeth 212 face the first teeth 211.

When the lock lever 110 is located at the release position P3, the second teeth 212 are disengaged from the first teeth 211. When the lock lever 110 is located at the fix position P4, the second teeth 212 fit in the first teeth 211. When the second teeth 212 fit in the first teeth 211, the first flap 53 is restricted to move.

The first teeth 211 are lined in the direction along the X axis. Moving the first flap 53 in the direction along the X axis moves the first teeth 211 with respect to the second teeth 212 of the lock lever 110. Moving the first flap 53 to a desired position and moving the lock lever 110 from the release position P3 to the fix position P4 restrict the first flap 53 to move at the desired position. More specifically, the lock lever 110 restricts the first flap 53 to move at the first position P1 and at a plurality of positions different from the first position P1 and the second position P2. The different positions are examples of third positions.

The holder 10 as in the foregoing can hold both the tablet 11 in a landscape orientation (indicated with the symbol 11H in FIG. 9) and the tablet 11 in a portrait orientation (indicated with the symbol 11V in FIG. 9), for example. The long direction of the landscape-oriented tablet 11H (the direction from the first side face 32 of the cover 16 toward the second side face 33, for example) is along the X axis. The long direction of the portrait-oriented tablet 11V is along the Z axis.

The following describes one example of a method of supporting the landscape-oriented tablet 11H by the holder 10 in the second embodiment. First, the lock lever 110 is moved to the release position P3. The first flap 53 is then separated from the second flap 54 and moved to the second position P2.

Next, the lower face 35 of the cover 16 for the tablet 11 is made to hit against the second supporting wall 208 of the second flap 54. More specifically, the second supporting wall 208 supports the tablet 11. Furthermore, the second side face 33 of the cover 16 is made to hit against the second side wall 86 of the second flap 54. Consequently, the tablet 11 is sandwiched by the second front wall 87 and the second back wall 209.

The first flap 53 is then moved in the direction along the X axis. The first side wall 81 of the first flap 53 hits against the first side face 32 of the cover 16 for the tablet 11. More specifically, the first side wall 81 and the second side wall 86 sandwich the tablet 11. This makes the holder 10 restrict the tablet 11 to move in the direction along the X axis. Furthermore, the first supporting wall 205 supports the lower face 35 of the cover 16.

When the first side wall 81 hits against the first side face 32 of the cover 16, the first protrusions 83 fit in the indentations 201 provided on the first side wall 81. This makes the holder 10 restrict the tablet 11 to move in the direction along the Z axis. Furthermore, the first front wall 82 and the first back wall 206 sandwich the tablet 11. This makes the holder 10 restrict the tablet 11 to move in the direction along the Y axis.

Next, the lock lever 110 located at the release position P3 is moved to the fix position P4. The second teeth 212 of the lock lever 110 fit in the first teeth 211 of the first arm 101. This restricts the first flap 53 to move, and the landscape-oriented tablet 11H is supported by the holder 10.

When the holder 10 holds the portrait-oriented tablet 11V, the first side wall 81 hits against the upper face 34 of the cover 16 for the tablet 11 and the second side wall 86 hits against the lower face 35 of the cover 16, for example. Furthermore, the first protrusions 83 of the first flap 53 fit in the indentations 201 provided on the upper face 34. The position of the first flap 53 when the holder 10 holds the portrait-oriented tablet 11V is closer to the second flap 54 than the position of the first flap 53 when the holder 10 holds the landscape-oriented tablet 11H.

In the holder 10 in accordance with the second embodiment, the lock lever 110 restricts the first flap 53 to move at the first position P1 and at least one position different from the first position P1 and the second position P2. This enables the holder 10 to support the tablet 11 in a plurality of orientations.

Moreover, the holder 10 can hold another electronic device, such as a cellular phone or a smartphone, the size of which is different from that of the tablet 11, for example. More specifically, the holder 10 in the second embodiment can support a plurality of types of electronic devices.

While the first flap 53 comprises the first protrusions 83 and the second flap 54 does not comprise the second protrusions 88 in the second embodiment, the present invention is not limited to this. For example, the first flap 53 may not comprise the first protrusions 83, and the second flap 54 may comprise the second protrusions 88.

In the embodiments in the foregoing, the end portions of the first indentations 44 in the direction along the Y axis are open. However, the end portions of the first indentations 44 in the direction along the Y axis may be closed. The first protrusions 83 fitting in such first indentations 44 makes the holder 10 restrict the tablet 11 to move not only in the direction along the Z axis but also in the direction along the Y axis.

The second connector 121 to be connected with the tablet 11 may be fixed to the first flap 53 or the second flap 54, for example. Then, it may be configured that moving the first flap 53 or the second flap 54 to the first position P1 inserts the terminal 122 of the second connector 121 to the first connector 23.

In accordance with at least one of the embodiments in the foregoing, the second member catches the recessed portion or the projecting portion of the electronic device. This prevents the electronic device from moving in the first direction from the position supported by the first member. Consequently, this prevents the electronic device from coming off from the support device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in the above-described embodiment, one example of the recessed portion or the projecting portion is the first and the second indentations 44 and 45. However, in place of the first and the second indentations 44 and 45, the projecting portion may be provided on the tablet 11, for example. In this case, the recessed portion configured to be catch the projecting portion is formed on the first and the second flaps 53 and 54, for example.

Furthermore, in the above-described embodiments, one example of the attachment is the cover 16 configured to be attached to the device 15. The attachment is, however, not limited to this, and may be a part of the housing 21 of the device 15, for example. More specifically, the attachment may be a part of the electronic device, or may be a separate component detachable from the electronic device.

Moreover, in place of the magnet 65, the back board 51 may be provided with a suction cup or a portion having adherence, for example. The suction cup or the portion having adherence adhering to the back face 46 of the cover 16 prevents the tablet 11 from coming off from the holder 10.

What is claimed is:

1. A support device configured to detachably support an electronic device, the electronic device comprising a first face configured to be projected an image and a second face comprising a recessed portion or a projecting portion, the support device comprising:
a first member configured to support the electronic device in a state in which the first face is visible; and
a second member configured to be engaged with the recessed portion or the projecting portion, and to be movable between a first position and a second position, the first position being a position at which the second member is engaged with the recessed portion or the projecting portion to suppress moving of the electronic device in at least a first direction along the second face from a position supported by the first member, the second position being a position at which the second member is configured to be separated further from the second face than when the second member is at the first position and at which the electronic device is configured to be permitted to move in the first direction from the supported position.

2. The support device of claim 1, further comprising:
a first wall configured to face an end portion at one side of the electronic device in a second direction crossing the first face; and
a second wall configured to face an end portion at other side of the electronic device in the second direction.

3. The support device of claim 2, further comprising a locking portion configured to be movable between a fix position and a release position, the fix position being a position at which the locking portion is configured to restrict the second member to move, the release position being a position at which the locking portion is configured to release the restriction of the second member to move.

4. The support device of claim 3, further comprising a biasing portion configured to push the second member toward the first position.

5. The support device of claim 4, wherein the locking portion at the fix position is configured to restrict the second member to move at the first position and at least one third position different from the first position and the second position.

6. The support device of claim 5, wherein an end portion at one side of the electronic device in the first direction is configured to be exposed in a state that the second member is at the first position and the electronic device is supported.

7. The support device of claim 6, further comprising an engaging portion configured to engage a first connecting portion, the first connecting portion being configured to be detachably connected to a second connecting portion on the electronic device.

8. The support device of claim 7, wherein
the first member comprising an opening through which wiring extending from the first connecting portion is configured to pass, and
the engaging portion is provided at an edge portion of the opening.

9. An attachment configured to be supported by a support device, to be attached to an electronic device, and to constitute an electronic device assembly, the support device being configured to detachably support the electronic device assembly, the support device comprising a first member and a second member, the first member being configured to support the electronic device assembly comprising a first face and a second face in a state in which the first face is visible, the first face being configured to be projected an image, the second face comprising a recessed portion or a projecting portion, the second member being configured to be engaged with the recessed portion or the projecting portion and to be movable between a first position and a second position, the first position being a position at which the second member is engaged with the recessed portion or the projecting portion to suppress moving of the electronic device assembly in at least a first direction along the second face from a position supported by the first member, the second position being a position at which the second member is configured to be separated further from the second face than when the second member is at the first position and at which the electronic device assembly is configured to be permitted to move in the first direction from the supported position, the attachment comprising:
the second face comprising the recessed portion or the projecting portion, wherein
the attachment is configured to cover the electronic device and to expose the first face.

10. A method of supporting an electronic device performed by a support device configured to detachably support the electronic device, the electronic device comprising a first face configured to project an image and a second face comprising a recessed portion or a projecting portion, the support member comprising a first member and a second member, the first member being configured to support the electronic device in a state in which the first face is visible, the second member being configured to be engaged with the recessed portion or the projecting portion and to be movable between a first position and a second position, the first position being a position at which the second member is engaged with the recessed portion or the projecting portion to suppress moving of the electronic device in at least a first direction along the second face from a position supported by the first member, the second position being a position at which the second member is configured to be separated further from the second face than when the second member is at the first position and at which the electronic device is configured to be permitted to move in the first direction from the supported position, the method comprising:
supporting the electronic device by the first member; and
engaging the recessed portion or the projecting portion with an engaging portion of the second member moved from the second position to the first position, so as to suppress moving of the electronic device in the first direction from the supported position.
